(19) United States
(12) Patent Application Publication
(10) Pub. No.: US 2025/0176339 A1
(43) Pub. Date: May 29, 2025

(54) OPTOELECTRONIC SEMICONDUCTOR DEVICE AND METHOD OF MAKING THE SAME

(71) Applicant: UNIKORN SEMICONDUCTOR CORPORATION, Hsinchu (TW)

(72) Inventors: Hsin-Chung Hsu, Hsinchu (TW); Tai-I Yang, Hsinchu (TW); Hao-Ming Ku, Hsinchu (TW); Hong-Chou Chuang, Hsinchu (TW)

(21) Appl. No.: 18/958,266

(22) Filed: Nov. 25, 2024

(30) Foreign Application Priority Data
Nov. 27, 2023 (TW) 112145756

(51) Int. Cl. H01L 33/62; H01L 33/22

(52) U.S. Cl. CPC H10H 20/857; H10H 20/82; H10H 20/0364

(57) ABSTRACT

The disclosure relates to an optoelectronic semiconductor device. The optoelectronic semiconductor device includes a base, a semiconductor stack on the base, a bonding layer between the semiconductor stack and the base, a metal layer on the semiconductor stack and including a first width, and a first electrode pad covering the metal layer and the semiconductor stack. The first electrode pad includes a first region surrounding the metal layer and a second region surrounding the first region. The first region has a first roughness and a second width, and the second region has a second roughness different from the first roughness.

### CROSS REFERENCE TO RELATED APPLICATIONS

This Application claims priority of Taiwan Patent Application No. 112145756, filed on Nov. 27, 2023, the entirety of which is incorporated by reference herein.

### BACKGROUND

### Field of the Application

The disclosure relates to semiconductor technologies, and, in particular to optoelectronic semiconductor device and method of making the same.

### Description of the Related Art

Semiconductor devices are widely used, and the research and development of related materials is also continuously being carried out. For example, III-V semiconductor materials may be applied to various optoelectronic semiconductor devices, such as light-emitting chips (e.g., light-emitting diodes or laser diodes), light-absorbing chips (e.g., photodetectors or solar cells) or non-luminous chips (e.g., power components of switches or rectifiers), which can be used in lighting, medical treatment, display, communication, sensing, power supply systems and other applications.

With the developments in science and technology, optoelectronic semiconductor devices have gradually been miniaturized. Due to breakthroughs in the dimensions of light-emitting diodes (LEDs) in recent years, micro-LED displays, which are made by arranging light-emitting diodes in an array, are gradually gaining attention in the market. Compared with organic light-emitting diode (OLED) displays, micro-LED displays are more power-efficient, have better reliability, longer service life and better contrast performance, while being visible in sunlight. With the development of technology, there are still many technical researching needs for optoelectronic semiconductor devices. Although existing optoelectronic semiconductor devices generally meet requirements, they are not satisfactory in all respects, and further improvements are still needed.

### SUMMARY

An embodiment of the disclosure provides an optoelectronic semiconductor device includes a base, a semiconductor stack on the base, a bonding layer between the semiconductor stack and the base, a metal layer on the semiconductor stack and including a first width, and a first electrode pad covering the metal layer and the semiconductor stack. The first electrode pad includes a first region surrounding the metal layer and a second region surrounding the first region. The first region has a first roughness and a second width, and the second region has a second roughness different from the first roughness.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIGS. 1-3 are cross-sectional views of various stages of making an optoelectronic semiconductor device, in accordance with one embodiment.

FIGS. 4-5 are exemplary processes of a thermal process, in accordance with some embodiments.

FIGS. 6-7 are cross-sectional views of various stages of making an optoelectronic semiconductor device, in accordance with another embodiment.

FIG. 8 is a cross-sectional view of an optoelectronic semiconductor device having a first electrode pad and a second electrode pad, in accordance with another embodiment.

FIG. 9 is a scanning electron microscopy image of a portion of the optoelectronic semiconductor device shown in FIG. 8.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Unless otherwise defined, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or context of the present disclosure, and should not be interpreted in an idealized or overly formal manner unless so defined.

Traditional thermal process is carried out by rapid thermal annealing (RTA) process, which including placing the devices in a quartz tube, with dozens of infrared lamps mounted around the quartz tube. These infrared lamps are used to irradiate the device for heating, allowing an interface between a semiconductor stack and a metal layer on the device to form ohmic contact.

Since the components in the optoelectronic semiconductor device have similar absorption efficiencies for infrared light, when the metal layer is heated to the temperature required for forming ohmic contact, a bonding layer between a substrate and the semiconductor layer may degrade due to its inability to withstand the temperature. Consequently, after the rapid thermal annealing process, the bonding layer may exhibit abnormal phenomena such as charring or formation of holes.

In accordance with some embodiments of the present disclosure, a heat source in the thermal process can be middle infrared light heating process or microwave heating process. Since the metal layer and the bonding layer have different absorption efficiencies to the heat source, the chamber temperature can be maintained below the thermal decomposition temperature of the bonding layer while still allowing the metal layer and the semiconductor stack to reach the temperature required to form ohmic contact. This approach prevents the degradation of the bonding layer, thereby improving the yield of the optoelectronic semiconductor device and solving problems arising from the bonding layer after rapid thermal annealing.

Some variations of the embodiments are described below. In the different drawings and illustrated embodiments, the same or similar reference numbers are used to designate the same or similar features. It is understood that additional operations can be provided before, during, and/or after the methods, and some of the described steps can be replaced or omitted for other embodiments of the methods.

In order to help the person having ordinary skill in the art better understand the aspects of the present disclosure, the structure of the optoelectronic semiconductor device 100 is simplified, and not all features of the optoelectronic semiconductor device 100 are illustrated or described in detail. The optoelectronic semiconductor device 100 can be light-emitting chips (e.g., light-emitting diodes or laser diodes), light-absorbing chips (e.g., photodetectors or solar cells), or non-luminous chips (e.g., power components of switches or rectifiers). In some embodiments, the optoelectronic semiconductor device 100 may be a micro light emitting diode (Micro LED).

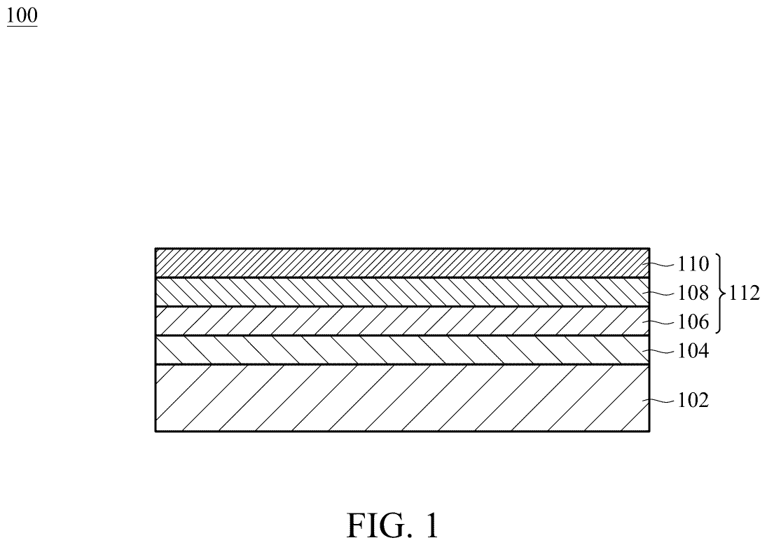

FIGS. 1-3 are cross-sectional views of various stages of making an optoelectronic semiconductor device 100, in accordance with some embodiments. Referring to FIG. 1, in some embodiments of the present disclosure, a base 102 is provided, and a semiconductor stack 112 is disposed on the base 102. The semiconductor stack 112 is bonded to the base 102 through a bonding layer 104.

In some embodiments, the base 102 may include insulating or non-insulating materials. Insulating materials may include sapphire, glass, or ceramic materials. Non-insulating materials may include elemental semiconductors (such as silicon (Si) or germanium (Ge)), compound semiconductors (such as silicon carbide (SiC), gallium nitride (GaN), aluminum gallium nitride (AlGaN), aluminum nitride (AlN), gallium arsenide (GaAs) or a combination thereof), metals (such as copper (Cu), molybdenum (Mo), or copper tungsten (CuW)), or a combination thereof. The base 102 may be multi-layered, such as silicon-on-insulator.

In some embodiments, the semiconductor stack 112 may include a first semiconductor structure 106, an active structure 108, and a second semiconductor structure 110 stacked in sequence. In some embodiments, the doping procedure in the first semiconductor structure 106 and the second type semiconductor structure 114 may be performed by in-situ doping during epitaxial growth process and/or implanting doping after epitaxial growth process. The first semiconductor structure 106 may include a first dopant and have a first conductivity type, while the second semiconductor structure 110 may include a second dopant and have a second conductivity type. The first semiconductor structure 106 and the second semiconductor structure 110 have different conductivity types; that is, the first conductivity type is opposite to the second conductivity type. For example, the first conductivity type may be p-type, while the second conductivity type may be n-type, providing electric holes and electrons, respectively. Alternatively, the first conductivity type may be n-type, while the second conductivity type may be p-type, to provide electrons and electric holes, respectively.

In some embodiments of the present disclosure, the first semiconductor structure 106, the active structure 108, and the second semiconductor structure 110 may include III-V semiconductor materials, such as aluminum (Al), gallium (Ga), arsenic (As), phosphorus (P), indium (In) or nitrogen (N). Specifically, the III-V semiconductor materials may be a binary compound semiconductor, such as gallium arsenide (GaAs), gallium phosphide (GaP), gallium nitride (GaN), or indium phosphide (InP); ternary compound semiconductors, such as indium gallium arsenide (InGaAs), aluminum gallium arsenide (AlGaAs), gallium indium phosphide (GaInP), aluminum indium phosphide (AlInP), gallium indium nitride (InGaN), or aluminum nitride gallium nitride (AlGaN); or quaternary compound semiconductors, such as aluminum gallium indium arsenide (AlGaInAs), aluminum gallium indium phosphide (AlGaInP), aluminum indium gallium nitride (AlInGaN), indium gallium arsenide phosphide (InGaAsP), indium gallium arsenide nitride (InGaAsN), or aluminum gallium arsenide phosphide (AlGaAsP).

In some embodiments, the active structure 108 may include a structure of multi quantum wells (MQWs). When the optoelectronic semiconductor device 100 is driven, the active structure 108 emits light. The light emitted from the active structure 108 may include visible or non-visible light. The wavelength of the light emitted from the optoelectronic semiconductor device 100 depends on the material and composition of the active structure 108. For example, a blue or deep blue light with a peak wavelength ranging from 400 nm to 490 nm, green light with a peak wavelength ranging from 490 nm to 550 nm, or red light with a peak wavelength ranging from 560 nm to 650 nm can be emitted when the material of the active structure 108 includes InGaN. An ultraviolet light with a peak wavelength ranging from 250 nm to 400 nm can be emitted when the material of the active structure 108 includes AlGaN or AlInGaN. An infrared light with a peak wavelength ranging from 700 nm to 1700 nm can be emitted when the material of the active structure 108 includes InGaAs, InGaAsP, AlGaAs, or AlGaInAs. A red light with a peak wavelength ranging from 610 nm to 700 nm or yellow light with a peak wavelength ranging from 530 nm to 600 nm can be emitted when the material of the active structure 108 includes GaInP or AlGaInP.

In some embodiments, the semiconductor stack 112 may be formed by deposition or epitaxial process. Deposition process includes physical vapor deposition (PVD), atomic layer deposition (ALD), and metal-organic chemical vapor deposition (MOCVD). Epitaxy process may include molecular beam epitaxy (MBE), liquid phase epitaxy (LPE), vapor phase epitaxy (VPE), atomic layer epitaxy (ALE), or a combination thereof.

In accordance with some embodiments, the formation of the optoelectronic semiconductor device 100, as shown in FIG. 1, includes forming a semiconductor stack 112 on an additional growth substrate (not shown) using method such as metal-organic chemical vapor deposition (MOCVD), hydride vapor phase epitaxy (HVPE), molecular beam epitaxy (MBE), liquid-phase epitaxy (LPE), or vapor phase epitaxy (VPE). Then, the growth substrate is flipped and the semiconductor stack is bonded to the base 102 through the bonding layer 104. Afterward, the growth substrate is removed. In other words, the second semiconductor structure 110, the active structure 108, the first semiconductor structure 106, and the bonding layer 104 are sequentially formed on the growth substrate. Then, the base 102 and the semiconductor stack 112 are bonded to each other through the bonding layer 104. Afterward, the growth substrate is removed. Therefore, in various embodiments of the present disclosure, the vertical order of the features in the figures does not represent their actual formation sequence.

In some embodiments of the present disclosure, the bonding layer 104, which is configured to bond the semiconductor stack 112 to the base 102, may include polymer materials, compound materials, or a combination thereof. Polymer materials include benzocyclobutene (BCB) or polyimide (PI). Compound materials include silicon dioxide (SiO₂), titanium dioxide (TiO₂), tantalum pentoxide (Ta₂O₅), alumina (Al₂O₃) or silicon nitride (SiNₓ). In some embodiments, the bonding layer 104 may be formed by spin coating and thermal processes. In some embodiments, the bonding layer 104 has a thermal decomposition temperature, which is between 380° C. and 400° C., but the present disclosure is not limited thereto.

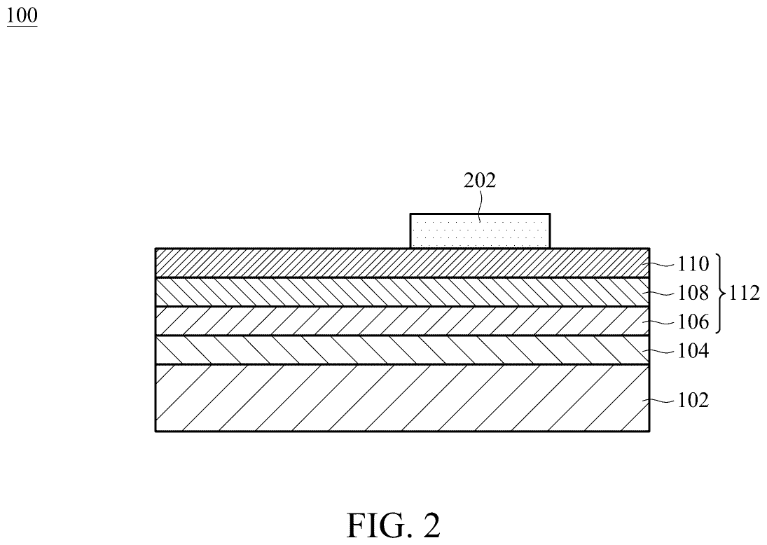

Referring to FIG. 2, in some embodiments of the present disclosure, the metal layer 202 is formed on the second semiconductor structure 110 of the semiconductor stack 112. Specifically, a metal film is formed on the semiconductor stack 112, and the metal film is in direct contact with a top surface of the second semiconductor structure 110. Then, the metal film is patterned to form the metal layer 202 by an etching process.

In some embodiments, the metal layer 202 may include multiple layers or a single layer and include metal materials or alloy materials, such as chromium (Cr), titanium (Ti), nickel (Ni), gold (Au), platinum (Pt), molybdenum (Mo), aluminum (Al), silicon (Si), tungsten (W), copper (Cu), tantalum (Ta), or alloys of the aforementioned metal materials. In some embodiments, the metal layer 202 includes beryllium gold (BeAu) or germanium gold (GeAu). In some embodiments, the formation of the metal layer 202 may include forming a metal film using a deposition process, and then patterning the metal film through an etching process.

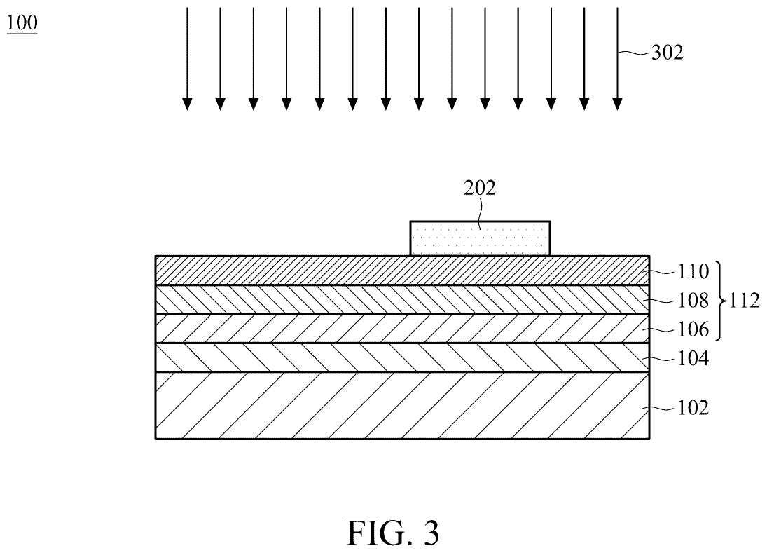

Referring to FIG. 3, in accordance with some embodiments of the present disclosure, in the method of making the optoelectronic semiconductor device 100, after forming the metal layer 202, a thermal process 302 may be performed to ensure good ohmic contact is formed at the interface between the metal layer 202 and the semiconductor stack 112. In some embodiments of the present disclosure, the optoelectronic semiconductor device 100 is placed in a thermal chamber, and the thermal process 302 is performed at a chamber temperature below the thermal decomposition temperature of the bonding layer 104. In some embodiments, the chamber temperature is below 420° C. (preferably below 400° C.).

If the chamber temperature during the thermal process 302 exceeds 420° C. (or exceeds 400° C.), it may cause degradation of the bonding layer 104, leading to abnormal phenomena in the optoelectronic semiconductor device 100. For example, the bonding layer 104 is polyimide (PI) with a thermal decomposition temperature of 400° C., and the chamber temperature may be adjusted to remain below 400° C. to prevent degradation of the bonding layer 104, which could lead to surface abnormalities in the optoelectronic semiconductor device 100. However, the present disclosure is not limited thereto.

In some embodiments, the thermal process 302 may be a microwave heating process or a middle infrared (MIR) heating process. During the optoelectronic semiconductor device 100 is preformed the thermal process 302, which is the microwave heating process or the MIR heating processes, the chamber temperature can be maintained below the thermal decomposition temperature of the bonding layer 104, while enabling the interface between the semiconductor stack 112 and the metal layer 202 to achieve ohmic contact. This approach prevents the degradation of the bonding layer 104, thereby improving the yield of optoelectronic semiconductor device 100 and solving problems arising from the bonding layer 104 after rapid thermal annealing.

In some embodiments where the thermal process 302 is a microwave heating process, the microwaves can induce currents in the metal. Therefore, utilizing this characteristic, when the optoelectronic semiconductor device 100 is irradiated with microwaves, the metal layer 202 generates induced currents, converting electrical potential into heat energy, which enables ohmic contact at the interface between the metal layer 202 and the semiconductor stack 112. Meanwhile, polymer materials of the bonding layer 104 do not heat up when microwaves are applied, preventing degradation of the bonding layer 104, thereby improving the yield of optoelectronic semiconductor device 100. In some embodiments, the thickness of metal layer 202 may be less than 100 μm and higher than 1 μm. In some embodiments, the frequency of the microwaves is between 2 GHz and 10 GHz. If the frequency is less than 2 GHZ, the microwave energy is too weak to effectively achieve ohmic contact at the interface between the metal layer 202 and the semiconductor stack 112. Conversely, if the frequency is greater than 10 GHz, the microwave energy becomes too strong and might damage the semiconductor stack 112.

In some embodiments where the thermal process 302 is a middle infrared heating process, the absorption efficiency of metal is significantly higher than that of polymer materials. Therefore, utilizing this characteristic, when the metal layer 202 absorbs middle infrared energy and achieves ohmic contact at the interface with the semiconductor stack 112, the lower absorption efficiency of the bonding layer 104 ensures that the temperature of the bonding layer 104 does not reach the thermal decomposition temperature. This prevents the degradation of the bonding layer 104, thereby improving the yield of optoelectronic semiconductor device 100. In some embodiments, the middle infrared light has a wavelength that is between 1.5 μm and 10 μm. If the wavelength is less than 1.5 μm, most of the light will penetrate the metal layer 202 and the semiconductor stack 112, preventing effective absorption by the metal. Conversely, if the wavelength exceeds 10 μm, a longer heating time will be required to achieve ohmic contact, which may reduce throughput.

In some embodiments, according to process requirements, the thermal process 302 may be one-stage heating, multi-stage heating or pulse heating. In some embodiments where the thermal process 302 is microwave heating process or middle infrared heating process combined with one-stage heating, the chamber temperature is raised directly from room temperature to the target temperature and held for a duration. The target temperature and duration can be adjusted as needed. For example, the thermal process 302 is microwave one-stage heating process, the target temperature may between 380° C. and 420° C.

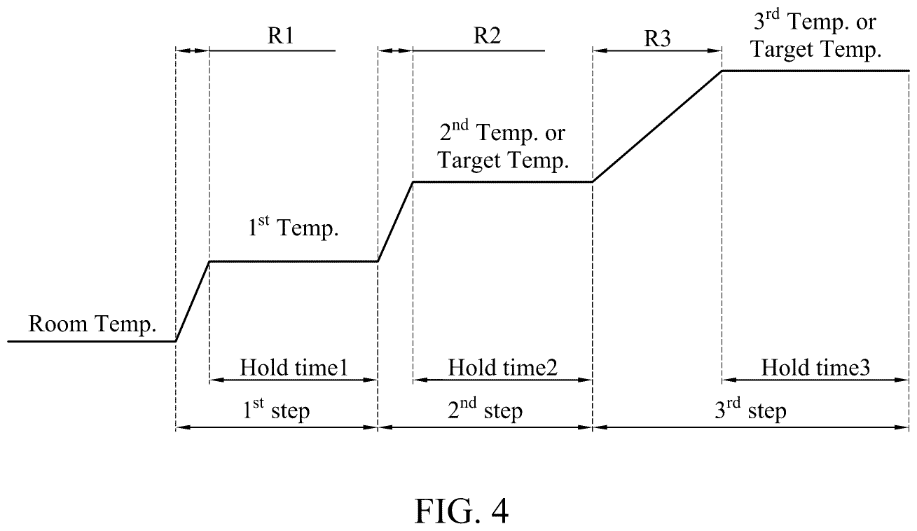

FIG. 4 is an exemplary process of the thermal process 302, in accordance with some embodiments: the multi-stage heating process, which can reduce thermal stress generated during the thermal process. In some embodiments where the thermal process 302 is microwave heating process or middle infrared heating process combined with multi-stage heating, the chamber temperature is raised from room temperature to a first-stage setting temperature and held for a duration, defining one stage. Then, the chamber temperature is raised from the first-stage setting temperature to a second-stage setting temperature, which can be the target temperature, and held for a duration. If the second-stage temperature does not meet the target, the chamber temperature is raised to a third-stage setting temperature, which can also be the target temperature, and held for a duration. If the third-stage setting temperature does not meet the target, the procedure will continue, repeating multiple stages until the target temperature is achieved.

For example, the target temperature can between 380° C. and 420° C. The setting temperatures for each stage may be determined based on the heating rates and the number of stages. If the target temperature is 400° C., the room temperature is 26° C., and there are two stages having the same heating rate, the first-stage setting temperature can be 213° C., and the second-stage setting temperature (i.e., the target temperature) can be 400° C. The heating rates for each stage may differ from one another, and the duration of each stage can be adjusted according to their respective setting temperatures.

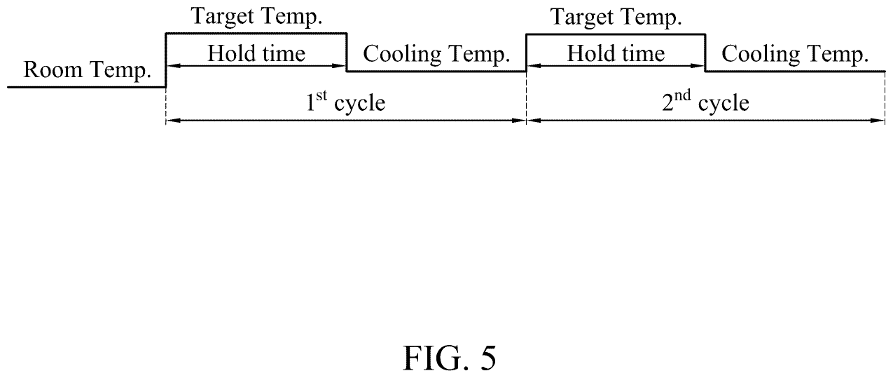

FIG. 5 shows another exemplary process of the thermal process 302, which is the pulse heating process., The pulse heating process facilitates easier control of the process temperature, and ensures the chamber temperature below the thermal decomposition temperature of the bonding layer. In some embodiments where the thermal process 302 is microwave heating process or middle infrared heating process combined with pulse heating, the chamber temperature is raised from room temperature to the target temperature and held for a duration, followed by a decrease to the cooling temperature. Afterward, the temperature is raised from the cooling temperature to the target temperature, defining a cycle that can be repeated multiple times. The target temperature, duration, cooling temperature, and number of cycles can be customized and adjusted according to requirements. For example, in some embodiments where the thermal process 302 is middle infrared pulse heating process, the target temperature can between 300° C. and 420° C., such as between 370° C. and 400° C.

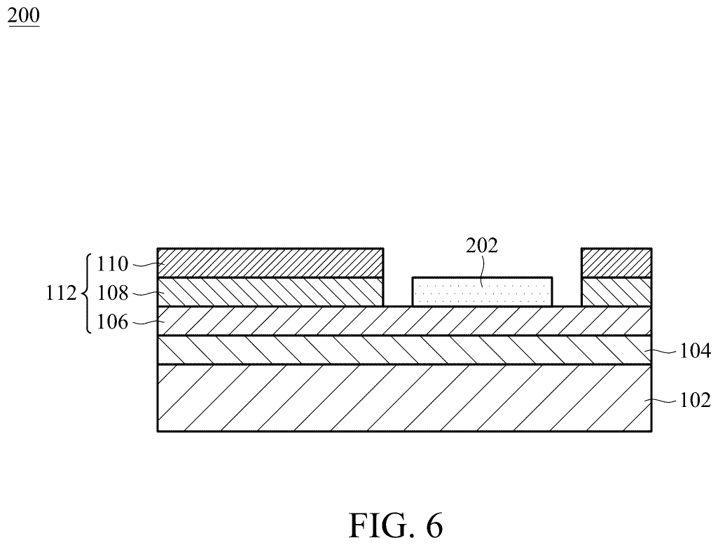

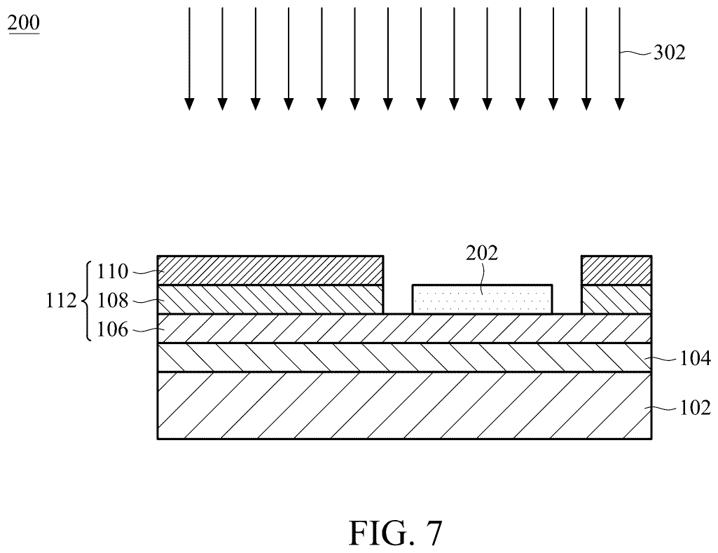

FIGS. 6-7 are cross-sectional views of various stages of making an optoelectronic semiconductor device, in accordance with another embodiment. As shown in FIG. 6, based on the conductivity types of the first semiconductor structure 106 and the second semiconductor structure 110, as well as the process requirements, an optoelectronic semiconductor device 200 may be formed, which is similar to the optoelectronic semiconductor device 100 described in FIG. 2. The difference between the optoelectronic semiconductor device 200 and the optoelectronic semiconductor device 100 is that, prior to forming the metal layer 202, an etching process is performed to remove a portion of the active structure 108 and a portion of the second semiconductor structure 110, thereby exposing a portion of the first semiconductor structure 106.

The etching process may include, for example, a dry etching process, a wet etching process, or a combination thereof. For example, the dry etching process may include plasma etching (PE), reactive ion etching (RIE), or inductively coupled plasma reactive ion etching (ICP-RIE).

Referring now to FIG. 7, after forming the metal layer 202, the thermal process 302 described in FIG. 3 may be applied to the optoelectronic semiconductor device 200 for achieving good ohmic contact at the interface between the metal layer 202 and the semiconductor stack 112. The thermal process 302 has been described in detail in previous embodiments, and those descriptions will not be repeated herein for brevity.

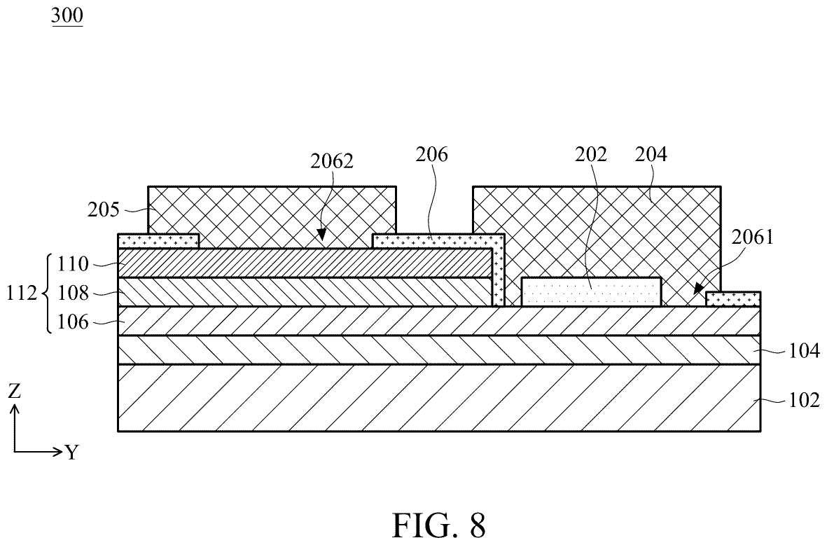

FIG. 8 is a cross-sectional view of an optoelectronic semiconductor device 300, in accordance with another embodiment. The optoelectronic semiconductor device 300 has structures and processes similar to those of the optoelectronic semiconductor device 200. Specifically, after applying the thermal process 302 to the optoelectronic semiconductor device 300, an insulating structure 206, a first electrode pad 204, and a second electrode pad 205 are formed on the semiconductor stack 112. Specifically, the insulating structure 206 covers the sidewalls of the second semiconductor structure 110, the sidewalls of the active structure 108, a portion of the upper surface of the first semiconductor structure 106, and a portion of the upper surface of the second semiconductor structure 110. The insulating structure 206 includes a first opening 2061 that exposes the first semiconductor structure 106 and the metal layer 202, and a second opening 2062 that exposes the second semiconductor structure 110. The first electrode pad 204 covers the metal layer 202, a portion of the first semiconductor structure 106, and a portion of the second semiconductor structure 110. The second electrode pad 205 is located on the second semiconductor structure 110 and is physically separated from the first electrode pad 204. The first electrode pad 204 is electrically connected to the first semiconductor structure 106, while the second electrode pad 205 is electrically connected to the second semiconductor structure 110. In other embodiments, the optoelectronic semiconductor structure may optionally include a contact layer (not shown) located between the second electrode pad 205 and the second semiconductor structure 110.

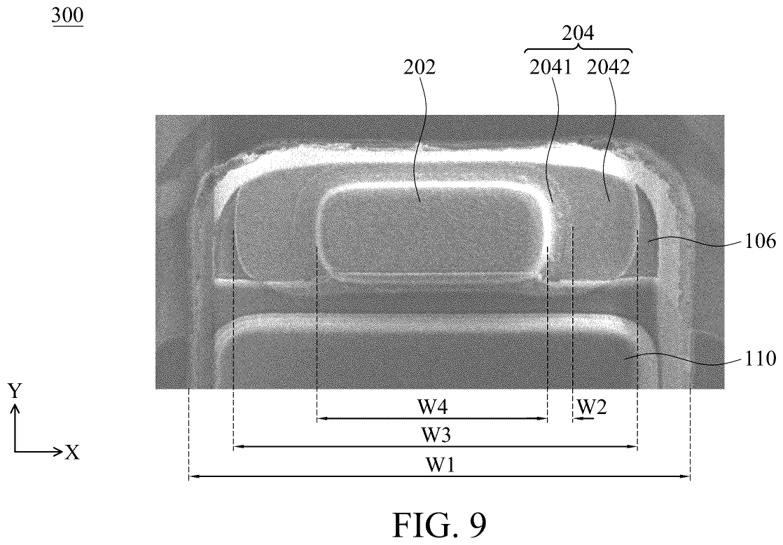

FIG. 9 is a scanning electron microscopy image of a portion of the optoelectronic semiconductor device 300 shown in FIG. 8. In a top view of the optoelectronic semiconductor device 300, the first electrode pad 204 covers the semiconductor stack 112 (first semiconductor structure 106) and the metal layer 202 and includes a first region 2041 and a second region 2042. More specifically, the first region 2041 and the second region 2042 located on the first semiconductor structure 106, and the first region 2041 surrounds the metal layer 202 and the second region 2042 surrounds the first region 2041. That is, the second region 2042 is farther away from metal layer 202 than the first region 2041. In other words, the second region 2042 surrounds the first region 2041. The first region 2041 has a profile (rounded rectangle) that is substantially the same as that of the metal layer 202. In this embodiment, the first region 2041 has a first roughness, while the second region 2042 has a second roughness that is different from the first roughness. Specifically, in this embodiment, the first roughness is greater than the second roughness. In the horizontal direction (e.g., in the X direction as shown in FIG. 9), the optoelectronic semiconductor device 300 has a first width W1, the first region 2041 has a second width W2, the electrode pad 204 has a third width W3, and the metal layer 202 has a fourth width W4. A ratio of the fourth width W4 to the second width W2 (W4/W2) is between 10 and 15. A ratio of the third width W3 to the second width W2 (W3/W2) is between 16 and 23. A ratio of the first width W3 to the second width W2 (W1/W2) is between 24 and 30.

In some embodiments, after applying the thermal process 302 to the optoelectronic semiconductor devices 100, 200, and 300 to achieve ohmic contact at the interface between the semiconductor stack 112 and the metal layer 202, additional processes may be included, such as singulation, transfer, and packaging.

In summary, the optoelectronic semiconductor devices 100, 200, and 300 of the present disclosure utilize middle infrared light or microwaves as a heat source. Since the metal layer and the bonding layer have different absorption efficiencies to the heat source, the chamber temperature can be maintained below the thermal decomposition temperature of the bonding layer 104 while achieving the temperature required for forming ohmic contact between the metal layer 202 and the semiconductor stack 112. This approach prevents the degradation of the bonding layer 104, thereby improving the yield of the optoelectronic semiconductor device and solving problems arising from the bonding layer after rapid thermal annealing.

The aforementioned embodiments are merely illustrative of the principles and effects of the present disclosure and are not intended to limit the concept. It will be apparent to those skilled in the art that various modifications and variations can be made without departing from the spirit and scope of the present disclosure, which remains within its intended range.

The features between the various embodiments can be combined and used interchangeably as long as they do not violate or conflict with the spirit of the disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. Therefore, the scope of the present disclosure includes the aforementioned processes, machines, manufacture, composition, devices, methods, and steps. Any embodiment or claim of the present disclosure should not achieve all of the objectives, advantages, and/or features disclosed herein.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optoelectronic semiconductor device, comprising:
a base;
a semiconductor stack on the base;
a bonding layer between the semiconductor stack and the base;
a metal layer on the semiconductor stack and including a first width; and
a first electrode pad covering the metal layer and the semiconductor stack, and comprising a first region surrounding the metal layer and a second region surrounding the first region;
wherein the first region has a first roughness and a second width, and the second region has a second roughness different from the first roughness.

2. The optoelectronic semiconductor device of claim 1, wherein a ratio of the first width to the second width is between 10 and 15.

3. The optoelectronic semiconductor device of claim 1, wherein the first roughness of the first region is larger than the second roughness of the second roughness.

4. The optoelectronic semiconductor device of claim 1, wherein the optoelectronic semiconductor device comprises a third width, and a ratio of the third width to the second width is between 24 and 30.

5. The optoelectronic semiconductor device of claim 1, wherein the first electrode pad comprises a fourth width, and a ratio of the fourth width to the second width is between 16 and 23.

6. The optoelectronic semiconductor device of claim 1, further comprising a second electrode pad on the semiconductor stack and separated from the first electrode pad.

7. The optoelectronic semiconductor device of claim 1, wherein the optoelectronic semiconductor device is a micro light emitting diode.

8. The optoelectronic semiconductor device of claim 1, wherein the bonding layer comprises benzocyclobutene (BCB), polyimide (PI), silicon dioxide (SiO₂), titanium dioxide (TiO₂), tantalum pentoxide (Ta₂O₅), alumina (Al₂O₃) or silicon nitride (SiNₓ).

9. The optoelectronic semiconductor device of claim 1, wherein the metal layer comprises a thickness less than 100 μm and higher than 1 μm.

10. The optoelectronic semiconductor device of claim 1, wherein a profile of the first region is substantially the same as a profile of the metal layer.

11. A method of making an optoelectronic semiconductor device, comprising:
disposing a semiconductor stack on a base, wherein the semiconductor stack is bonded to the base through a bonding layer;
disposing a metal layer on the semiconductor stack; and
performing a thermal process to form an ohmic contact between the metal layer and the semiconductor stack, wherein the thermal process is performed at a temperature below a thermal decomposition temperature of the bonding layer.

12. The method of making an optoelectronic semiconductor device of claim 11, wherein the semiconductor stack comprises:
a first semiconductor structure;
an active structure on the first semiconductor structure; and
a second semiconductor structure on the active structure.

13. The method of making an optoelectronic semiconductor device of claim 12, further comprising:
forming a first electrode pad electrically connected to the first semiconductor structure; and
forming a second electrode pad electrically connected to the second semiconductor structure.

14. The method of making an optoelectronic semiconductor device of claim 12, further comprising:
before forming the metal layer, performing an etching process to remove portions of the active structure and the second semiconductor structure to expose a portion of the first semiconductor structure.

15. The method of making an optoelectronic semiconductor device of claim 11, wherein the thermal process comprises a microwave heating process.

16. The method of making an optoelectronic semiconductor device of claim 15, wherein a frequency of microwave during the microwave heating process is between 2 GHz and 10 GHz.

17. The method of making an optoelectronic semiconductor device of claim 11, wherein the thermal process comprises a middle infrared heating process.

18. The method of making an optoelectronic semiconductor device of claim 17, wherein the middle infrared heating process comprises a middle infrared light with a wavelength between 1.5 μm and 10 μm.

19. The method of making an optoelectronic semiconductor device of claim 11, wherein the thermal process comprises one-stage heating process, multi-stage heating process or pulse heating process.

20. The method of making an optoelectronic semiconductor device of claim 11, wherein the temperature is between 300° C. and 420° C.
